(19) United States
(12) Patent Application Publication
(10) Pub. No.: US 2021/0405787 A1
(43) Pub. Date: Dec. 30, 2021

(54) TOUCH CONTROL PANEL

(71) Applicant: TCL China Star Optoelectronics Technology Co., LTD., Shenzhen,Guangdong (CN)

(72) Inventor: Gu HUANG, Shenzhen (CN)

(21) Appl. No.: 16/617,148

(22) PCT Filed: Sep. 11, 2019
(86) PCT No.: PCT/CN2019/105310

§ 371 Date: Nov. 26, 2019

(30) Foreign Application Priority Data
Jul. 29, 2019 (CN) 201910689435.4

(51) Int. Cl. G06F 3/041; G06F 3/044; H05K 1/18

(52) U.S. Cl. CPC G06F 3/0412; G06F 3/0446; H05K 2201/10128; H05K 1/189; G06F 3/04164

(57) ABSTRACT

The present invention discloses a touch control panel, including: an upper polarizer, a color filter glass, a TFT glass, a lower polarizer, a PCB board, a flexible circuit board, a touch control driver, and a first touch control layer and a second touch control layer formed on both sides of the upper polarizer. The first touch control layer includes a plurality of first touch control electrodes; the second touch control layer includes a plurality of second touch control electrodes; and the plurality of first touch control electrodes and the plurality of second touch control electrodes are crisscrossed.

### FIELD OF INVENTION

The disclosure relates to the touch control display technology field, and more particularly, to a touch control panel.

### BACKGROUND OF INVENTION

With the rapid development of display technology, touch control products have gradually spread throughout people's lives. Touch control products include touch control screen panel. Currently, touch control screen panels can be divided into external type, on cell type, in cell type, etc., according to composition structure.

In general on cell type, sensors used for touch control sensing are generally disposed on color filter glass, and then bonded to the color filter glass using a flexible circuit board. Then whether the flexible circuit board is bonded to a PCB of a driving module of a display panel according to actual needs. The difficulty with this type of solution is that the color filter glass needs to be bonded. Hence, a part of the color filter glass needs to be bonded, and the area thereof cannot be a display area, leading to a lower screen-to-body ratio. Furthermore, when a single touch control or display module is damaged, the entire touch control display screen needs to be replaced, which wastes resources. In addition, if the mutual capacitive sensor uses a single-layer multi-touch control caterpillar scheme, touch control performance is poor; meanwhile, if a multilayer multi-touch bridging scheme is used, a plurality of photomasks is needed, which has higher costs.

### SUMMARY OF INVENTION

Most of the mutual capacitive sensor in the prior art uses a single-layer multi-touch control caterpillar scheme, touch control performance is poor; meanwhile, if a multilayer multi-touch bridging scheme is used, a plurality of photomasks is needed, which has higher costs.

To achieve the above object, the present disclosure provides a display control panel.

A touch control panel comprises an upper polarizer, a color filter glass, a TFT glass, a lower polarizer, a PCB board, a flexible circuit board, a touch control driver, which are disposed in sequence, and a first touch control layer and a second touch control layer formed on both sides of the upper polarizer, the first touch control layer comprises a plurality of first touch control electrodes, the second touch control layer comprises a plurality of second touch control electrodes, wherein, the plurality of first touch control electrodes of the first touch control layer are sensing channels, the plurality of second touch control electrodes of the second touch control layer are driving channels, wherein, the plurality of first touch control electrodes and the plurality of second touch control electrodes are crisscrossed.

According to the touch control panel of the present disclosure, the lower polarizer is disposed on a bottom layer, the TFT glass is disposed above the lower polarizer, the color filter glass is disposed above the TFT glass, and the upper polarizer is disposed above the color filter glass, one end of the flexible circuit board is connected to the first touch control layer and the second touch control layer, the other end of the flexible circuit board is connected to the PCB board, and the touch control driver is connected to the PCB board.

According to the touch control panel of the present disclosure, an interval is formed between the color filter glass and the TFT glass thereby resulting in the color filter glass not being contacted with the TFT glass.

According to the touch control panel of the present disclosure, the first touch control layer is disposed on an upper side of the upper polarizer, and the second touch control layer is disposed on a lower side of the upper polarizer.

According to the touch control panel of the present disclosure, an interval is formed between the first touch control layer and the second touch control layer thereby resulting in the first touch control layer not being contacted with the second touch control layer.

According to the touch control panel of the present disclosure, a capacitor is formed at a crossover point of the plurality of first touch control electrodes of the first touch control layer and the plurality of second touch control electrodes of the second touch control layer.

According to the touch control panel of the present disclosure, the plurality of first touch control electrodes of the first touch control layer are horizontally arranged, and the plurality of second touch control electrodes of the second touch control layer are vertically arranged.

According to the touch control panel of the present disclosure, the plurality of first touch control electrodes of the first touch control layer are vertically arranged, and the plurality of second touch control electrodes of the second touch control layer are horizontally arranged.

To achieve the above object, the present disclosure provides a display control panel comprising an upper polarizer, a color filter glass, a TFT glass, a lower polarizer, a PCB board, a flexible circuit board, a touch control driver, which are disposed in sequence, and a first touch control layer and a second touch control layer formed on both sides of the upper polarizer, the first touch control layer comprises a plurality of first touch control electrodes, the second touch control layer comprises a plurality of second touch control electrodes, wherein, the plurality of first touch control electrodes and the plurality of second touch control electrodes are crisscrossed.

According to the touch control panel of the present disclosure, the lower polarizer is disposed on a bottom layer, the TFT glass is disposed above the lower polarizer, the color filter glass is disposed above the TFT glass, and the upper polarizer is disposed above the color filter glass, one end of the flexible circuit board is connected to the first touch control layer and the second touch control layer, the other end of the flexible circuit board is connected to the PCB board, and the touch control driver is connected to the PCB board.

According to the touch control panel of the present disclosure, an interval is formed between the color filter glass and the TFT glass thereby resulting in the color filter glass not being contacted with the TFT glass.

According to the touch control panel of the present disclosure, the first touch control layer is disposed on an upper side of the upper polarizer, and the second touch control layer is disposed on a lower side of the upper polarizer.

According to the touch control panel of the present disclosure, the plurality of first touch control electrodes of the first touch control layer are sensing channels.

According to the touch control panel of the present disclosure, wherein the plurality of second touch control electrodes of the second touch control layer are driving channels.

According to the touch control panel of the present disclosure, wherein an interval is formed between the first touch control layer and the second touch control layer thereby resulting in the first touch control layer not being contacted with the second touch control layer.

According to the touch control panel of the present disclosure, wherein a capacitor is formed at a crossover point of the plurality of first touch control electrodes of the first touch control layer and the plurality of second touch control electrodes of the second touch control layer.

According to the touch control panel of the present disclosure, wherein the plurality of first touch control electrodes of the first touch control layer are horizontally arranged, and the plurality of second touch control electrodes of the second touch control layer are vertically arranged.

According to the touch control panel of the present disclosure, wherein the plurality of first touch control electrodes of the first touch control layer are vertically arranged, and the plurality of second touch control electrodes of the second touch control layer are horizontally arranged.

The embodiment of the present disclosure provides an on cell type mutual capacitive touch control panel, which integrates a double-sided ITO sensor used for touch control sensing into the polarizer of the display panel, which can effectively improve the screen-to-body ratio, and is advantageous for replacing single damaged touch control or display module. Furthermore, it also reduces the number of photomasks of the touch control display panel to reduce cost.

### DESCRIPTION OF DRAWINGS

FIG. 1 is a schematic structural diagram of a touch control panel according to an embodiment of the present disclosure.

FIG. 2 is a top schematic view of a first touch control layer and a second touch control layer according to an embodiment of the present disclosure.

### DETAILED DESCRIPTION OF PREFERRED EMBODIMENTS

The following description of the embodiments with reference to the appended drawings is used for illustrating specific embodiments which may be used for carrying out the present disclosure.

In order to make the above and other objects, features and advantages of the present disclosure more obvious and understandable, the following description of preferred embodiment with reference to the accompanying drawings is used to exemplify a specific embodiment.

Furthermore, the directional terms described by the present disclosure, such as upper, lower, top, bottom, front, back, left, right, inner, outer, side, surrounding, center, horizontal, vertical, axial, radial, uppermost layer or lowermost layer, etc., are only directions by referring to the accompanying drawings. Thus, the used directional terms are adopted to describe and understand the present disclosure, but the present disclosure is not limited thereto.

In the figures, elements with similar structures are indicated by the same numbers.

The present disclosure provides a touch control panel, which integrated a double-sided ITO sensor for touch control sensing into the polarizer of the display panel, which can effectively improve the screen-to-body ratio, and is advantageous for replacing single damaged touch control or display module.

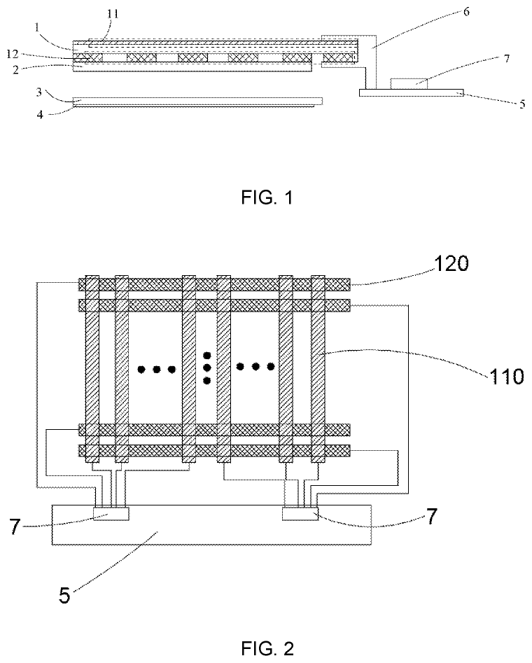

FIG. 1 is a schematic structural diagram of a touch control panel according to an embodiment of the present disclosure. As shown as FIG. 1, the embodiment of the present disclosure provides the touch control panel, comprising an upper polarizer 1, a color filter glass 2, a TFT glass 3, a lower polarizer 4, a PCB board 5, a flexible circuit board 6, a touch control driver 7, and a first touch control layer 11 and a second touch control layer 12 formed on upper and lower layers of the upper polarizer 1. The first touch control layer 11 comprises a plurality of first touch control electrodes 110; the second touch control layer 12 comprises a plurality of second touch control electrodes 120; wherein, the plurality of first touch control electrodes 110 and the plurality of second touch control electrodes 120 are crisscrossed.

Wherein, the lower polarizer 4 is disposed on a bottom layer, the TFT glass 3 is disposed above the lower polarizer 4, the color filter glass 2 is disposed above the TFT glass 3, and the upper polarizer 1 is disposed above the color filter glass 2, one end of the flexible circuit board 6 is connected to the first touch control layer 11 and the second touch control layer 12 of the upper and lower layers of the upper polarizer 1, the other end of the flexible circuit board 6 is connected to the PCB board 5, and the touch control driver 7 is connected to the PCB board 5.

As shown as FIG. 1, in the touch control panel of the embodiment of the present disclosure, an interval exists between the color filter glass 2 and the TFT glass 3 thereby resulting in the color filter glass 2 not being in direct contact with the TFT glass 3.

In the present embodiment, the plurality of first touch control electrodes 110 and the plurality of second touch control electrodes 120 are respectively disposed on the upper and lower layers of the upper polarizer 1 of the display panel. The plurality of first touch control electrodes 110 and the plurality of second touch control electrodes 120 are connected to the touch control driver 7 of the PCB board 5 by the bonding of flexible circuit board 6.

The touch control panel of the embodiment of the present disclosure is on the cell type touch control panel.

FIG. 2 is a top schematic view of the first touch control layer 11 and the second touch control layer 12 in the embodiment of the present disclosure. As shown as FIG. 2, wherein, the plurality of first touch control electrodes 110 are disposed at equal intervals, and the plurality of first touch control electrodes 110 are made of a transparent conductive film material. The plurality of second touch control electrodes 120 are disposed at equal intervals, and the plurality of second touch control electrodes 120 are made of a transparent conductive film material. It should be noted that, materials of the plurality of first touch control electrodes 110 and the plurality of second touch control electrodes 120 may be the same or different, and the embodiment of the present disclosure takes the same material as an example.

The first touch control layer 11 is disposed on the top layer of the upper polarizer 1, and the second touch control layer 12 is disposed on the bottom layer of the upper polarizer 1. The plurality of first touch control electrodes 110 of first touch control layer 11 is a sensing (RX) channel. The plurality of second touch control electrodes 120 of second touch control layer 12 is a driving (TX) channel. Furthermore, an interval is formed between the first touch control layer 11 and the second touch control layer 12 thereby resulting in the first touch control layer 11 not being in direct contact with the second touch control layer 12.

Wherein, the plurality of first touch control electrodes 110 of the first touch control layer 11 are horizontally arranged, and the plurality of second touch control electrodes 120 of the second touch control layer 12 are vertically arranged. Or, the plurality of first touch control electrodes 110 of the first touch control layer 11 are vertically arranged, and the plurality of second touch control electrodes 120 of the second touch control layer 12 are horizontally arranged. So long as directions of the plurality of first touch control electrodes 110 and the plurality of second touch control electrodes 120 are different, the embodiment of the present disclosure does not make any restrictions.

A sensing module consists of the plurality of first touch control electrodes 110, the plurality of second touch control electrodes 120, and the touch control driver 7. Wherein, a capacitor is formed at a crossover point of the plurality of first touch control electrodes 110 of the first touch control layer 11 and the plurality of second touch control electrodes 120 of the second touch control layer 12.

When the touch control panel is in operation, the touch control driver 7 continuously sends an excitation signal to each of the driving (TX) channels (the plurality of second touch control electrodes 120), and then receives a feedback signal from each of the sensing (RX) channels (the plurality of first touch control electrodes 110), to detect the capacitance of each of the capacitors formed by the driving (TX) channel and the sensing (RX) channel crisscrossed on a touch control sensor. When a finger touches the capacitor, since human hands are grounded, the driving (TX) channel and the sensing (RX) channel of the monitored capacitor are respectively connected a grounded capacitor, so that the capacitance detected by the touch control driver changes. The touch control driver can calculate position touched by the finger according to capacitance change of the corresponding capacitor corresponding to the corresponding sensing (RX) channel and the driving (TX) channel.

Although the present invention is described via one or more embodiments, a person of ordinary skill in the art can come up with equivalent variations and modifications based upon the understanding of the present specification and the accompanying drawings. The present invention includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the present specification shown herein. In addition, although a particular feature in the present specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

The embodiment of the present disclosure has been described with reference to the preferred embodiments thereof. It is noted that a person having ordinary skill in the art may appreciate improvements and modifications without departing from the principle of the present invention and, those improvements and modifications are considered within the scope of protection of the present invention.

What is claimed is:

1. A touch control panel, comprising: an upper polarizer, a color filter glass, a thin film transistor (TFT) glass, a lower polarizer, a printed circuit board (PCB), a flexible circuit board, a touch control driver, which are disposed in sequence, and a first touch control layer and a second touch control layer formed on both sides of the upper polarizer;
the first touch control layer comprises a plurality of first touch control electrodes; and
the second touch control layer comprises a plurality of second touch control electrodes;
wherein, the plurality of first touch control electrodes of the first touch control layer are sensing channels, and the plurality of second touch control electrodes of the second touch control layer are driving channels;
wherein, the plurality of first touch control electrodes and the plurality of second touch control electrodes are crisscrossed.

2. The touch control panel as claimed in claim 1, wherein the lower polarizer is disposed on a bottom layer, the TFT glass is disposed above the lower polarizer, the color filter glass is disposed above the TFT glass, and the upper polarizer is disposed above the color filter glass, one end of the flexible circuit board is connected to the first touch control layer and the second touch control layer, the other end of the flexible circuit board is connected to the PCB board, and the touch control driver is connected to the PCB board.

3. The touch control panel as claimed in claim 2, wherein an interval is formed between the color filter glass and the TFT glass thereby resulting in the color filter glass not being in direct contact with the TFT glass.

4. The touch control panel as claimed in claim 2, wherein the first touch control layer is disposed on an upper side of the upper polarizer, and the second touch control layer is disposed on a lower side of the upper polarizer.

5. The touch control panel as claimed in claim 1, wherein an interval is formed between the first touch control layer and the second touch control layer thereby resulting in the first touch control layer not being in direct contact with the second touch control layer.

6. The touch control panel as claimed in claim 5, wherein a capacitor is formed at a crossover point of the plurality of first touch control electrodes of the first touch control layer and the plurality of second touch control electrodes of the second touch control layer.

7. The touch control panel as claimed in claim 1, wherein the plurality of first touch control electrodes of the first touch control layer are horizontally arranged, and the plurality of second touch control electrodes of the second touch control layer are vertically arranged.

8. The touch control panel as claimed in claim 1, wherein the plurality of first touch control electrodes of the first touch control layer are vertically arranged, and the plurality of second touch control electrodes of the second touch control layer are horizontally arranged.

9. A touch control panel, comprising: an upper polarizer, a color filter glass, a thin film transistor (TFT) glass, a lower polarizer, a printed circuit board (PCB), a flexible circuit board, a touch control driver, which are disposed in sequence, and a first touch control layer and a second touch control layer formed on both sides of the upper polarizer;
the first touch control layer comprises a plurality of first touch control electrodes; and
the second touch control layer comprises a plurality of second touch control electrodes;
wherein, the plurality of first touch control electrodes and the plurality of second touch control electrodes are crisscrossed.

10. The touch control panel as claimed in claim 9, wherein the lower polarizer is disposed on a bottom layer, the TFT glass is disposed above the lower polarizer, the color filter glass is disposed above the TFT glass, and the upper polarizer is disposed above the color filter glass, one end of the flexible circuit board is connected to the first touch control layer and the second touch control layer, the other end of the flexible circuit board is connected to the PCB board, and the touch control driver is connected to the PCB board.

11. The touch control panel as claimed in claim 10, wherein an interval is formed between the color filter glass and the TFT glass thereby resulting in the color filter glass not being in direct contact with the TFT glass.

12. The touch control panel as claimed in claim 10, wherein the first touch control layer is disposed on an upper side of the upper polarizer, and the second touch control layer is disposed on a lower side of the upper polarizer.

13. The touch control panel as claimed in claim 9, wherein the plurality of first touch control electrodes of the first touch control layer are sensing channels.

14. The touch control panel as claimed in claim 9, wherein the plurality of second touch control electrodes of the second touch control layer are driving channels.

15. The touch control panel as claimed in claim 9, wherein an interval is formed between the first touch control layer and the second touch control layer thereby resulting in the first touch control layer not being in direct contact with the second touch control layer.

16. The touch control panel as claimed in claim 15, wherein a capacitor is formed at a crossover point of the plurality of first touch control electrodes of the first touch control layer and the plurality of second touch control electrodes of the second touch control layer.

17. The touch control panel as claimed in claim 9, wherein the plurality of first touch control electrodes of the first touch control layer are horizontally arranged, and the plurality of second touch control electrodes of the second touch control layer are vertically arranged.

18. The touch control panel as claimed in claim 9, wherein the plurality of first touch control electrodes of the first touch control layer are vertically arranged, and the plurality of second touch control electrodes of the second touch control layer are horizontally arranged.
